(19) United States
(12) Patent Application Publication
(10) Pub. No.: US 2010/0264957 A1
(43) Pub. Date: Oct. 21, 2010

(54) OUTPUT CIRCUIT

(76) Inventor: Shuji TAMAOKA, Kyoto (JP)

Correspondence Address: MCDERMOTT WILL & EMERY LLP, 600 13TH STREET, NW, WASHINGTON, DC, 20005-3096, US

(21) Appl. No.: 12/763,753

(22) Filed: Apr. 20, 2010

(30) Foreign Application Priority Data
Apr. 21, 2009 (JP) 2009-103159

(51) Int. Cl. H03K 3/00

(52) U.S. Cl. 327/109

(57) ABSTRACT

An output circuit includes: an NMOS transistor of an output buffer, a transistor ON drive circuit configured to turn on the transistor; a switchable current source configured to turn off the transistor; and a drive control circuit configured to control the transistor ON drive circuit and the switchable current source. The electric charge at the gate terminal of the NMOS transistor of the output buffer is pulled out with the current of the switchable current source at a fixed current value even when the gate voltage of the transistor varies in a range of variations of the threshold voltage Vth of the transistor.

### CROSS-REFERENCE TO RELATED APPLICATION

This application claims priority to Japanese Patent Application No. 2009-103159 filed on Apr. 21, 2009, the disclosure of which including the specification, the drawings, and the claims is hereby incorporated by reference in its entirety.

### BACKGROUND

The present disclosure relates to an output circuit included in a semiconductor integrated circuit device.

FIG. 18 shows a conventional output circuit. An output circuit of this type is described in Japanese Patent Publication No. 2007-150991 (Patent Document 1).

The above output circuit has such an effect that variations in the slew rate of an external output signal SC1 can be reduced even when the threshold voltage Vth (hereinafter simply referred to as Vth) of an NMOS transistor 15 varies, under an action as follows.

Referring to FIG. 18, in an output circuit 71 of a semiconductor integrated circuit 70, a control signal voltage change adjustment circuit 59 acts to reduce the drain current capability of PMOS transistors 10 and 62 when the Vth of the NMOS transistor 15 is small using its NMOS transistor 60 since the Vth of the NMOS transistor 60 is also small when the Vth of the NMOS transistor 15 is small. Likewise, the drain current capability of the PMOS transistors 10 and 62 is increased when the Vth of the NMOS transistor 15 is large using the NMOS transistor 60 whose Vth is also large. In this way, it is possible to reduce variations in the slew rate of the external output signal SC1 (the drain voltage of the NMOS transistor 15) that may occur with variations in the Vth of the NMOS transistor 15.

However, although the conventional circuit configuration shown in FIG. 18 has the effect of reducing variations in slew rate with variations in Vth when the NMOS transistor 15 is turned on, it has a problem that the effect of reducing variations in slew rate with variations in Vth does not work when the NMOS transistor 15 is turned off.

FIG. 19 is a signal waveform chart of the conventional output circuit shown in FIG. 18. With a change of an input signal SA1 of the output circuit from high to low, a signal SB1 for driving the gate of the NMOS transistor 15 changes from low to high. This turns on the NMOS transistor 15, whereby the external output signal SC1 makes a high to low transition.

Likewise, with a change of the input signal SA1 from low to high, the signal SB1 for driving the gate of the NMOS transistor 15 changes from high to low. This turns off the NMOS transistor 15, whereby the external output signal SC1 makes a low to high transition.

In the output circuit described above, when the Vth of the NMOS transistor 15 varies, it is possible to reduce variations in the falling slew rate of the external output signal SC1 at its high to low transition observed when the transistor 15 is turned on, under the action of the control voltage change adjustment circuit 59. However, it is not possible to reduce variations in the rising slew rate of the external output signal SC1 at its low to high transition observed when the transistor 15 is turned off.

Patent Document 1 mentioned above points out that the above problem can be solved with an output circuit as shown in FIG. 20. The output circuit shown in FIG. 20 has a configuration of the output circuit of FIG. 18 combined with an output circuit whose NMOS transistors and PMOS transistors are the reverse of those of the output circuit of FIG. 18.

A merit of the output circuit of FIG. 20 will be described with reference to a signal waveform chart of FIG. 21. When an input signal SA changes from high to low, a signal SBN for driving the gate of the NMOS transistor 15 goes high under the action of the control signal voltage change adjustment circuit 59. Simultaneously, since a PMOS transistor 211 is turned on, a signal SBP for driving the gate of a PMOS transistor 215 goes high.

The NMOS transistor 15 of an output buffer 8 is turned on with the low to high change of the signal SBN, while the PMOS transistor 215 of the output buffer 8 is turned off with the low to high change of the signal SBP. With the NMOS transistor 15 being turned on and thus driving a load 56, an external output signal SC makes a high to low transition.

When the input signal SA changes from low to high, the signal SBP for driving the gate of the PMOS transistor 215 goes low under the action of the control signal voltage change adjustment circuit 259. Simultaneously, since the NMOS transistor 11 is turned on, the signal SBN for driving the gate of the NMOS transistor 15 goes low. The PMOS transistor 215 of the output buffer 8 is turned on with the high to low change of the signal SBP, while the NMOS transistor 15 of the output buffer 8 is turned off with the high to low change of the signal SBN. With the PMOS transistor 215 being turned on and thus driving the load 56, the external output signal SC makes a low to high transition.

Thus, in the above output circuit, the high to low output falling transition of the external output signal SC is brought about when the NMOS transistor 15 is turned on, while the low to high output rising transition of the external output signal SC is brought about when the PMOS transistor 215 is turned on.

When the Vth of the NMOS transistor 15 varies, the control signal voltage adjustment circuit 59 acts to reduce variations in slew rate when the NMOS transistor 15 is turned on. In other words, the circuit 59 reduces variations in falling slew rate at the high to low transition of the external output signal SC.

When the Vth of the PMOS transistor 215 varies, the control signal voltage adjustment circuit 259 acts, like the control signal voltage adjustment circuit 59, to reduce variations in slew rate the PMOS transistor 215 is turned on. In other words, the circuit 259 reduces variations in rising slew rate at the low to high transition of the external output signal Sc.

Accordingly, in the output circuit of FIG. 20, no measures are necessary for reducing variations in slew rate with Vth variations at the drain output terminals of the transistors of the output buffer, such as the NMOS transistor 15 and the PMOS transistor 215, when the transistors are turned off.

However, the output circuit of FIG. 20 has a problem as follows. During a time period shown by mark (A) in FIG. 21, in which the signals SBP and SNB make a low to high transition simultaneously, the PMOS transistor 215 switches from on to off and simultaneously the NMOS transistor 15 switches from off to on. Therefore, there is a moment at which the two transistors 15 and 215 are both on. When the transistors 15 and 215 are both on, the power supply VDD and the ground GND are brought into conduction to each other via the two transistors, causing flow of a large current. This state is called a shoot through current condition of the PMOS transistor 215 and the NMOS transistor 15, and this large current is called a shoot through current.

Likewise, during a time period shown by mark (B) in FIG. 21, in which the signals SBP and SNB make a high to low transition simultaneously, the PMOS transistor 215 switches from off to on and simultaneously the NMOS transistor 15 switches from on to off. Therefore, there is a moment at which the two transistors are both on. With the two transistors being on simultaneously, the two transistors are in the shoot through current condition, and a large current, or a shoot through current, flows from the power supply VDD to the ground GND, as in the period (A) described above.

In the periods (A) and (B), because the shoot through current condition occurs in which a shoot through current flows from the power supply VDD to the ground GND through the NMOS transistor 15 and the PMOS transistor 215, the following problems may arise: the characteristic of the NMOS transistor 15 and the PMOS transistor 215 may deteriorate with time or the transistors break down, and noise may occur via power supply lines with fluctuations in power supply voltage VDD, causing malfunctions of the output circuit and other circuits.

As will be understood from the above description, in the output circuit of FIG. 20, if the load 56 is heavy and, for this reason, the NMOS transistor 15 and the PMOS transistor 215 constituting the output buffer 8 need to have a capability of driving a large current, the shoot through current will be a very large current. This output circuit therefore has a problem in reliability and lacks practicability.

In general, when the load 56 is heavy and thus the NMOS transistor 15 and the PMOS transistor 215 of the output buffer 8 need to have a large driving capability, the output circuit has a configuration as shown in FIG. 22.

In FIG. 22, an output inversion delay circuit 1 is a circuit that outputs the drive signal SBP for driving the PMOS transistor 215 of the output buffer 8 as a signal inverted form and delayed a given delay time behind the input signal SA. This circuit is therefore a circuit having both functions of a delay circuit and a pre-buffer circuit.

The output inversion delay circuit 1 generally has two different delay times: a delay time D1F at the high to low transition of the signal SA and a delay time D1R at the low to high transition of the signal SA.

Likewise, an output inversion delay circuit 2 is a circuit that outputs the drive signal SBN for driving the NMOS transistor 15 of the output buffer 8 as a signal inverted form and delayed a given delay time behind the input signal SA. This circuit is therefore a circuit having both functions of a delay circuit and a pre-buffer circuit.

The output inversion delay circuit 2 generally has two different delay times: a delay time D2F at the high to low transition of the signal SA and a delay time D2R at the low to high transition of the signal SA.

The delay times D1F and D2R may not be provided. The delay times D2F and D2R may be the same. The delay times D2F and D1R must be set to respective appropriate values to prevent occurrence of the shoot through current condition of the NMOS transistor 15 and the PMOS transistor 215 constituting the output buffer 8.

The operation of the output circuit of FIG. 22 will be described in detail with reference to a signal waveform chart of FIG. 23.

When the input signal SA changes from high to low, the output inversion delay circuit 1 changes the signal SBP for driving the gate of the PMOS transistor 215 from low to high after the lapse of the delay time D1F, to turn off the PMOS transistor 215. This delay time D1F is not necessarily required, but may be set as necessary for convenience of design of the output circuit.

Also, with the change of the input signal SA from high to low, the output inversion delay circuit 2 changes the signal SBN for driving the gate of the NMOS transistor 15 from low to high after the lapse of the delay time D2F, to turn on the NMOS transistor 15. This delay time D2F must be set so that the NMOS transistor 15 is turned on after the PMOS transistor 215 has been turned off. With this setting, the shoot through current condition in (A) shown in FIG. 21 can be prevented.

When the input signal SA changes from low to high, the output inversion delay circuit 2 changes the signal SBN for driving the gate of the NMOS transistor 15 from high to low after the lapse of the delay time D2R, to turn off the NMOS transistor 15.

The external output signal SC is kept low when the NMOS Transistor 15 is on because the transistor 15 drives the load 56. Once the NMOS transistor 15 is turned off ceasing driving the load 56, the external output signal SC rises up to the voltage VDD of the power supply to which one terminal of the load 56 has been pulled up. In other words, with the NMOS transistor 15 being turned off, the external output signal SC makes a low to high transition.

The above point differentiates the operation of the output circuit of FIG. 22 from that of the output circuit of FIG. 20. In the output circuit of FIG. 20, the external output signal SC makes a low to high transition with the PMOS transistor 215 being turned on. Also, the slew rate at this transition is determined with the state of the ON operation of the PMOS transistor 215, and the control signal voltage change adjustment circuit 259 controls the ON operation.

In the output circuit of FIG. 22, the slew rate at the low to high transition of the external output signal SC is determined with the state of the OFF operation of the NMOS transistor 15. Incidentally, as will be described later, it is an object of the present disclosure to control the slew rate of the external output signal SC with the OFF operation of the NMOS transistor 15 and reduce variations in slew rate even when the threshold voltage Vth of the transistor 15 varies.

Returning to the discussion on the operation of the output circuit of FIG. 22 with reference to the signal waveform chart of FIG. 23, the delay time D2R may not be provided as described above. Otherwise, the delay time D2R may be set so that the delay times of the output signal SC behind the input signal SA at the high to low falling transition and the low to high rising transition are equal to each other.

With the change of the input signal SA from low to high, also, the output inversion delay circuit 1 changes the signal SBP for driving the gate of the PMOS transistor 215 from high to low after the lapse of the delay time D1R, to turn on the PMOS transistor 215 thereby allowing an external terminal 54 of the output circuit to become high completely. The delay time D1R must be set so that the PMOS transistor 215 is turned on after the NMOS transistor 15 has been turned off. With this setting, the shoot through current condition in (B) shown in FIG. 21 can be prevented.

As will be understood from the above description, in the output circuit of FIG. 22, the slew rates of the external output signal SC at its high to low falling transition and low to high rising transition are determined with the ON and OFF operations of the NMOS transistor 15 of the output buffer 8. When the conventional output circuit of FIG. 18 is applied to the output circuit of FIG. 22, i.e., when the control signal voltage change adjustment circuit 59 shown in FIG. 18 is interposed between the output inverted delay circuit 2 and the NMOS transistor 15, the effect of reducing variations in slew rate with variations in the threshold voltage Vth of the NMOS transistor 15 will be obtained at the falling transition of the external output signal SC when the NMOS transistor 15 is turned on. However, this effect of reducing variations in slew rate with variations in Vth will not be obtained at the rising transition of the external output signal SC when the NMOS transistor 15 is turned off.

It is an object of the present invention to provide an output circuit in which, when the threshold voltage Vth of an output MOS transistor varies, variations in the slew rate of the drain voltage at the time when the output MOS transistor is turned off can be reduced.

Also, in output circuits like those shown in FIGS. 18 and 20 and other output circuits, the present invention is directed to reduce variations in slew rate with variations in Vth at a state transition of the external output signal SC by turning off a MOS transistor (an NMOS transistor or a PMOS transistor) of the output buffer.

### SUMMARY

The output circuit of the present disclosure includes, as shown in FIG. 1: a pre-drive circuit 1 configured to receive an input signal SA and output a drive signal SB; and a source-grounded, open-drain NMOS transistor 15 configured to receive the drive signal SB at its gate terminal and output an external output signal from its drain terminal.

The pre-drive circuit 1 includes: a transistor ON drive circuit 51 configured to output the drive signal SB for turning on the NMOS transistor 15; a current source 52 equipped with a switch function (switchable current source 52) configured to output the drive signal SB for turning off the NMOS transistor 15; and a drive control circuit 50 configured to output control signals Son and Soff for controlling the transistor ON drive circuit 51 and the switchable current source 52, respectively, in response to receipt of the input signal SA. The polarities of the input signal SA and the control signals Son and Soff are not specifically defined, and thus the polarity relationship between the input signal SA and the drive signal SB may be set arbitrarily.

The switchable current source 52 is connected to the gate of the NMOS transistor 15 at one terminal and to the ground GND at the other terminal. The switchable current source 52 having a current IG has a feature of pulling out electric charge at the gate terminal of the NMOS transistor 15 with a fixed current value even when the gate voltage of the NMOS transistor 15 varies in a range of variations of the threshold voltage Vth.

Alternatively, the output circuit of the present disclosure may be configured as shown in FIG. 3. That is, the switchable current source 52 is replaced with a variable current source equipped with a SW function (switchable variable current source) capable of changing the current value of the current IG of the switchable current source 52 with a current value change signal. Also, an output voltage detection circuit 2 is added, which changes the value of the current value change signal once the external output signal SC of the output circuit reaches a given voltage value and outputs the changed current value change signal to change the current value of the switchable variable current source 52.

The slew rate of the external output signal SC is determined mainly with the gate-drain capacitance value Cgd of the NMOS transistor 15 and the current value of the current IG of the switchable current source 52. The slew rate of the external output signal SC can be approximated by the following expression.

Slew rate≈(current value of current IG/Cgd) (1)

Expression (1) indicates that even when the threshold voltage Vth of the NMOS transistor 15 varies, the slew rate will not vary as long as the value of the current IG of the switchable current source 52 does not vary.

Referring to FIG. 2, the relationship between the OFF operation of the NMOS transistor 15 and the slew rate of the external output signal SC at its low to high transition in response to the OFF operation will be described in detail.

As the initial state, assume that, in response to the input signal SA, the drive signal SB from the pre-drive circuit 1 is high and the NMOS transistor 15 is on. As a result, the external output signal SC is low.

Once the polarity of the input signal SA changes, the control signal Soff from the drive control circuit 50 changes, causing the switchable current source 52 to pull the current IG to the ground GND so that the drive signal SB goes low. At this time, the output of the transistor ON drive circuit 51 is in High-impedance state in response to the signal Son from the drive control circuit 50, while the switchable current source 52 pulls out electric charge stored in the gate-source and gate-drain capacitances of the NMOS transistor 15 with the current IG. As a result, the gate voltage of the NMOS transistor 15 (the voltage of the drive signal SB) starts falling from high to low. Note that the gate-source and gate-drain capacitances of the NMOS transistor 15 are not shown in FIG. 1 because they are parasitic capacitances.

Once the gate voltage of the NMOS transistor 15 falls down to the threshold voltage Vth, the NMOS transistor 15 starts its OFF operation. At this time, the following two actions work on the gate of the NMOS transistor 15.

(1) With the OFF operation of the NMOS transistor 15, the drain terminal voltage of the transistor 15 (the voltage of the external output signal SC) is directed to rise to the power supply voltage VDD through the load 56 one of the terminals of which is pulled up to the power supply voltage VDD. As a result, since the capacitance Cgd exists between the gate and drain of the NMOS transistor 15, the gate voltage is directed to go high through this capacitance Cgd.

(2) As described above, the switchable current source 52 pulls the current IG from the gate terminal of the NMOS transistor 15 to act to drop the gate voltage to low.

The above two actions are balanced to stabilize the gate voltage of the NMOS transistor 15 at approximately the threshold voltage Vth. At this time, the NMOS transistor 15 is operating near the threshold between the ON and OFF states in which, while the NMOS transistor 15 is on, the drain terminal voltage is gradually making a low to high transition.

In the above state, the current IG of the switchable current source 52 flows to the gate-drain capacitance, changing the gate-drain voltage. The time differentiation of the gate-drain voltage Vgd at this time can be approximated by the following expression.

Time differentiation of Vgd≈(current value of current IG/Cgd) (2)

where Cgd denotes the gate-drain capacitance value of the NMOS transistor 15.

Since, in the above state, the gate voltage of the NMOS transistor 15 is stabilized at approximately the threshold voltage Vth as described above, the time differentiation of the gate-drain voltage Vgd is equivalent to the slew rate of the drain terminal voltage (the voltage of the external output signal SC). Accordingly, the slew rate of the external output signal SC satisfies Expression (1) above.

The situation where Expression (1) is satisfied continues until the drain terminal voltage reaches the voltage VDD. Once reaching the voltage VDD, the drain terminal voltage does not change. To satisfy the relationship of Expression (2), therefore, there is no choice but to reduce the gate voltage of the NMOS transistor 15. As a result, the NMOS transistor 15 settles into the OFF state.

As is found from Expression (1) above, the threshold voltage Vth is not directly related to the output slew rate. A main reason why the slew rate varies with variations in threshold voltage Vth is that the current value flowing to the gate changes with the threshold voltage Vth.

According to the present disclosure, the current IG of the switchable current source 52 for lowering the gate voltage of the NMOS transistor 15 (SB signal voltage) is designed so that its current value is invariable even in a range where the threshold voltage Vth varies.

As a result, in the output circuit of this disclosure, by setting the current value of the current IG appropriately, the slew rate at the time when the NMOS transistor 15 is turned off can be set to a desired value. Also, since the current value of the current IG is invariable even when the threshold voltage Vth varies, it is possible to obtain the effect of reducing variations in the slew rate of the external output signal SC when the NMOS transistor 15 is turned off.

Alternatively, according to the present disclosure, the configuration of the output circuit of FIG. 1 may be changed as shown in FIG. 3. That is, the switchable current source 52 is replaced with a switchable variable current source capable of changing the current value of the current IG of the switchable current source 52 with a current value change signal. Also, the output voltage detection circuit 2 is added, which changes the value of the current value change signal once the external output signal SC of the output circuit reaches a given voltage value to change the current value of the current IG of the switchable variable current source 52.

The effect of the above configuration will be described with reference to FIG. 4. In this circuit configuration, the current IG of the switchable variable current source 52 can be set to a large current value during a time period shown by (a) in FIG. 4, i.e., a time period in which the drive signal SB from the pre-drive circuit 1 transitions from high, where the NMOS transistor 15 is on, to low, where the gate voltage of the NMOS transistor 15 is stabilized at approximately the threshold voltage Vth, and the voltage of the output signal SC (drain terminal voltage) reaches a given voltage value from a low level (approximately 0 V).

With the above setting, it is possible to reduce variations in the time interval from the time point at which the voltage of the drive signal SB starts its high to low transition to the time point at which the voltage of the output signal SC rises from low.

As represented by Expression (1) above, the current value of the current IG of the switchable variable current source 52 determines the slew rate of the output signal SC. In the output circuit having the above configuration, by setting the current value of the current IG appropriately during a period (b), following the period (a), shown in FIG. 4 in which the output voltage reaches a high level (VDD voltage) from the given voltage value, a desired output voltage slew rate can be set.

Accordingly, in the output circuit having the above configuration, by setting different current values for the current IG between the periods (a) and (b), the slew rate can be set to a desired value when the NMOS transistor 15 is turned off, as in the above output circuit using the switchable current source. Also, since the current value of the current IG is invariable even when the threshold voltage Vth varies, it is possible to obtain the effect of reducing variations in the slew rate of the external output signal when the NMOS transistor 15 is turned off. In addition, unlike the above output circuit using the switchable current source, an effect of reducing variations in the delay time from the input signal SA to the output signal SC can be obtained even when the threshold voltage Vth varies.

### BRIEF DESCRIPTION OF THE DRAWINGS

FIG. 1 is a block diagram of an output circuit of the present disclosure.

FIG. 2 is a chart illustrating the operation of the output circuit of FIG. 1.

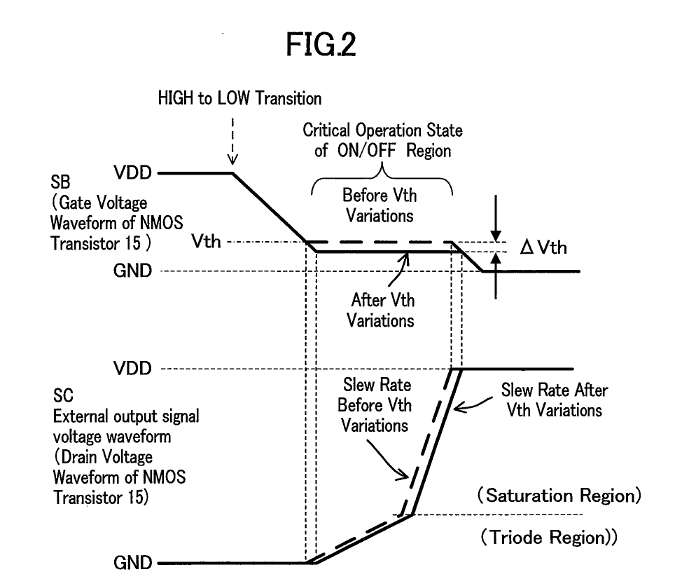

FIG. 3 is a block diagram of an output circuit modified from the output circuit of FIG. 1.

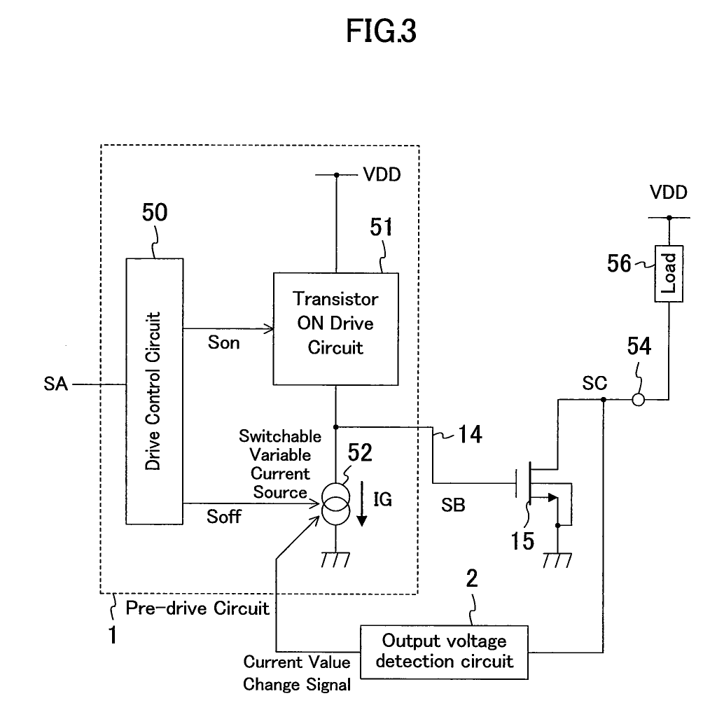

FIG. 4 is a chart illustrating the operation of the output circuit of FIG. 3.

FIG. 5 is a circuit diagram of an output circuit of Embodiment 1.

FIG. 6 is a view showing characteristics of the current of a switchable current source included in the output circuit of Embodiment 1.

FIG. 7 is a circuit diagram of an output circuit different in configuration from the output circuit of FIG. 5.

FIG. 8 is a circuit diagram of an output circuit of Embodiment 2.

FIG. 9 is a circuit diagram of an output circuit different in configuration from the output circuit of FIG. 8.

FIG. 10 is a circuit diagram of an output circuit of Embodiment 3.

FIG. 11A is a view showing a configuration of an output inversion delay circuit included in the output circuit of FIG. 10, and FIG. 11B is a chart illustrating the operation of the output inversion delay circuit.

FIG. 12 is a chart illustrating the operation of the output circuit of Embodiment 3.

FIG. 13 is a circuit diagram of an output circuit different in configuration from the output circuit of FIG. 10.

FIG. 14 is a chart illustrating the operation of the output circuit of FIG. 13.

FIG. 15 is a circuit diagram of an output circuit of Embodiment 4.

FIG. 16 is a chart illustrating the operation of the output circuit of Embodiment 4.

FIG. 17 is a circuit diagram of an output circuit of Embodiment 5.

FIG. 18 is a circuit diagram of a conventional output circuit.

FIG. 19 is a chart illustrating the operation of the output circuit of FIG. 18.

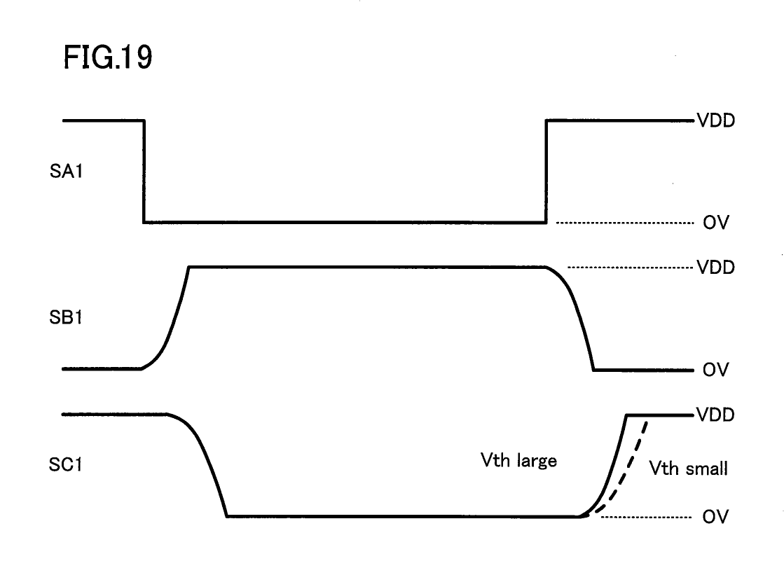

FIG. 20 is a circuit diagram of another conventional output circuit.

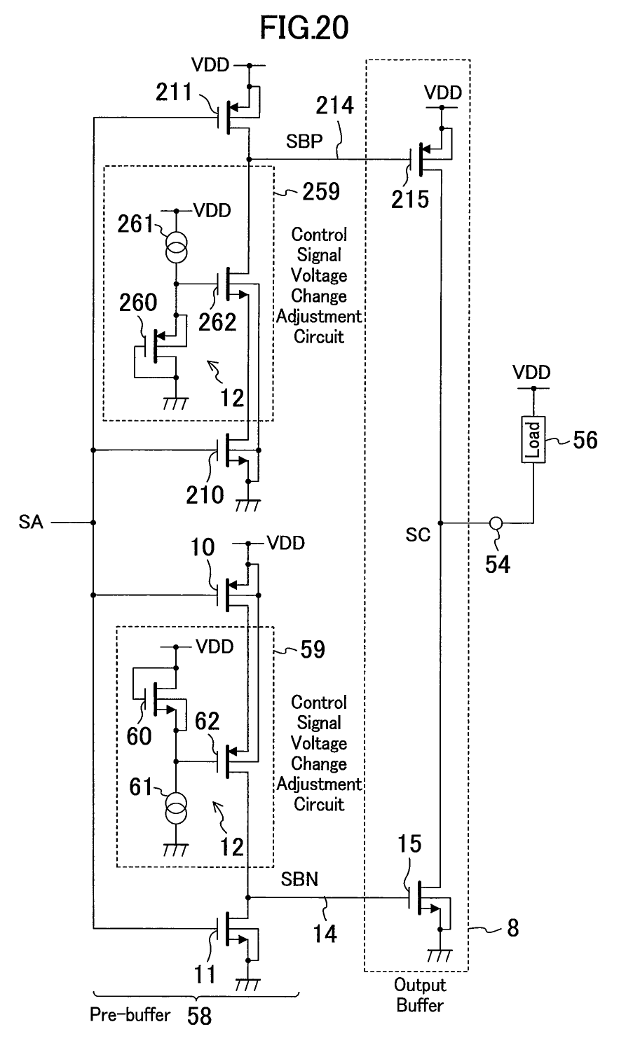

FIG. 21 is a chart illustrating the operation of the output circuit of FIG. 20.

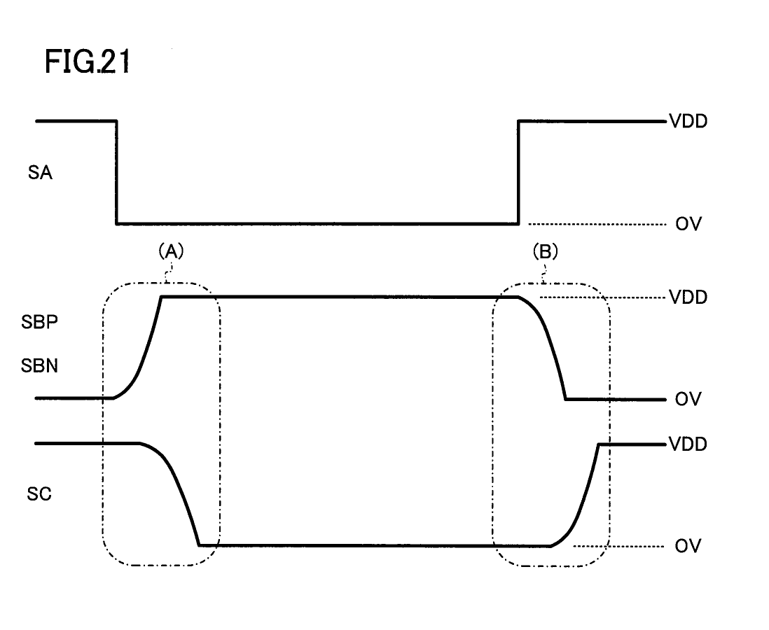

FIG. 22 is a circuit diagram of an output circuit with no shoot through between transistors of an output buffer.

FIG. 23 is a chart illustrating the operation of the output circuit of FIG. 22.

### DETAILED DESCRIPTION

Embodiments of the present invention will be described with reference to the accompanying drawings. Note that throughout the drawings, description of any identical or similar portions is not repeated in principle except when particularly necessary.

### Embodiment 1

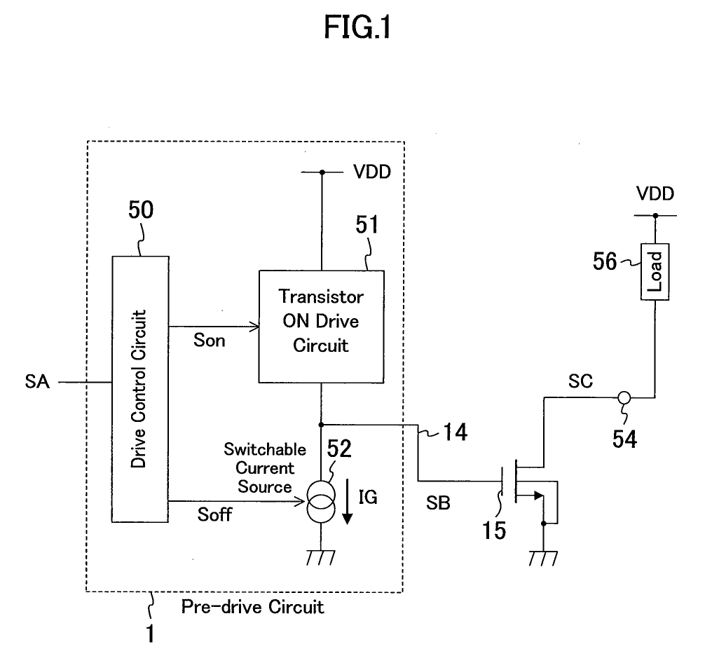

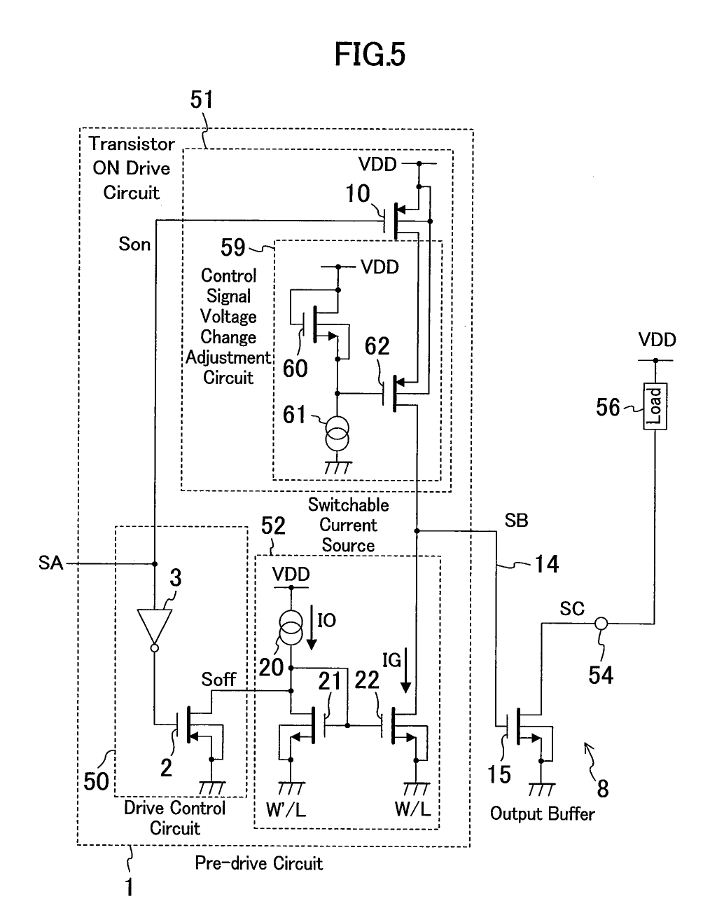

Embodiment 1 will be described with reference to FIG. 5. FIG. 5 shows an output circuit as a specific embodiment of the output circuit shown in FIG. 1. The configuration of the output circuit of Embodiment 1 shown in FIG. 5 will be described in association with FIG. 1.

The drive control circuit 50 in FIG. 1 includes an inverter 3 and an NMOS transistor 2 in this embodiment. The input signal SA is input into the gate terminal of the NMOS transistor 2 via the inverter 3, and the NMOS transistor 2 outputs the signal Soff for controlling the switchable current source 52 from its drain terminal. The input signal SA also serves as the signal Son as it is to drive the gate of a PMOS transistor 10 of the transistor ON drive circuit 51.

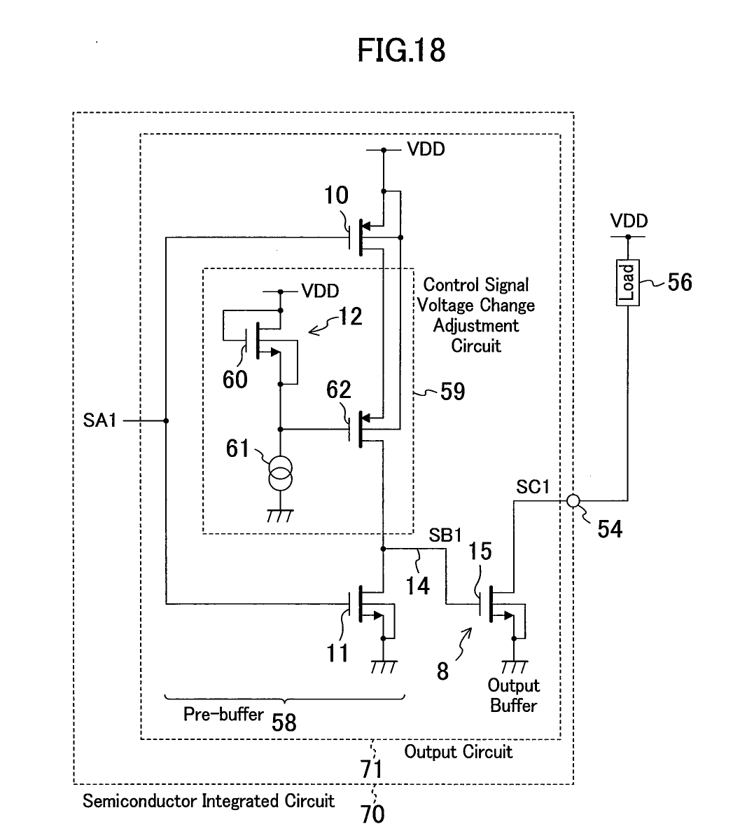

In FIG. 5, the transistor ON drive circuit 51 includes the control signal voltage change adjustment circuit 59 and the PMOS transistor 10 of the conventional output circuit shown in FIG. 18, to have the same configuration as the output circuit of FIG. 18. Having this configuration, it is possible to reduce variations in the slew rate of the external output signal SC with variations in the threshold voltage Vth of the NMOS transistor 15, if any, when the NMOS transistor 15 is turned on.

In FIG. 5, the switchable current source 52 includes a current mirror circuit having an NMOS transistor 21 and an NMOS transistor 22 for outputting the current IG of the switchable current source 52 and a current source 10 from which the current IG originates. The gate terminal of the NMOS transistor 15 of the output buffer 8 is connected to the drain terminal of the PMOS transistor 62 of the transistor ON drive circuit 51 and the drain terminal of the NMOS transistor 22 of the switchable current source 52. The drain terminal of the NMOS transistor 15, serving as the output terminal, outputs the external output signal SC. The load 56 connected to the output terminal at one terminal is pulled up to the power supply voltage VDD at the other terminal.

The signal Soff from the drive control circuit 50 is connected to the drain and gate terminals of the NMOS transistor 21 of the switchable current source 52. When the input signal SA is low, this node goes low, turning off the switchable current source 52 and thus dropping the current value of the current IG to zero.

With the configuration described above, in the output circuit of FIG. 5, when the input signal SA is high, the PMOS transistor 10 of the transistor ON drive circuit 51 is off, while the switchable current source 52 is on. Therefore, the gate drive signal SB for the NMOS transistor 15 of the output buffer 8 is low, and then the external output signal SC is high. Conversely, when the input signal SA is low, the PMOS transistor 10 of the transistor ON drive circuit 51 is on, while the switchable current source 52 is off. Therefore, the drive signal SB is high, and then the external output signal SC is low.

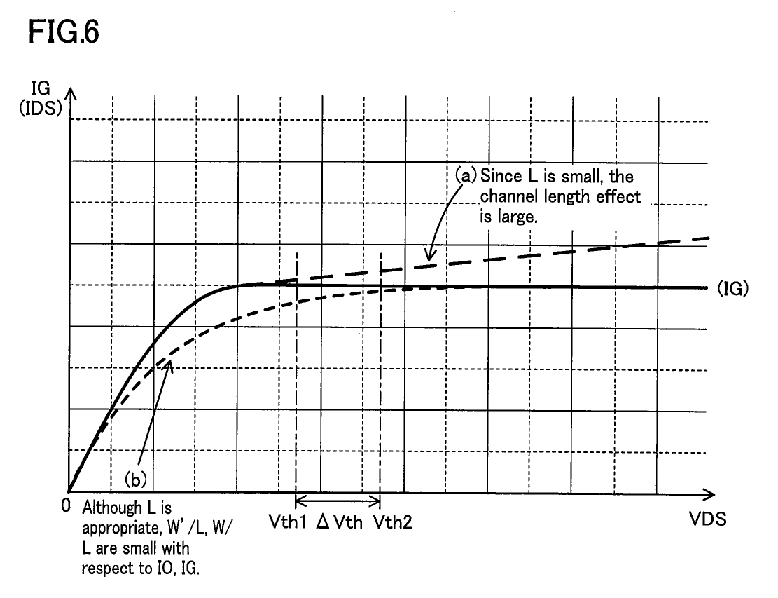

Like an IDS-VDS characteristic curve (IG) shown in FIG. 6, the current IG of the switchable current source 52 is made to keep a given constant current value in a range of variations of the threshold voltage Vth of the NMOS transistor 15 (range from Vth1 to Vth2 in FIG. 6). In other words, the current IG must avoid having a curve like characteristic curves (a) and (b) shown in FIG. 6.

To attain the above, it is necessary to set the channel length L of the NMOS transistors 21 and 22 at an appropriate value and set the respective channel widths W′ and W of the NMOS transistors 21 and 22 at appropriate values, so that W′/L and W/L are sufficiently large with respect to the current source JO and the output current IG.

It is assumed that the current source JO is produced to be independent of the threshold voltage Vth of the NMOS transistor 15. Also, the mirror ratio of the current IO to the current IG in the current mirror circuit having the NMOS transistors 21 and 22 is made independent of the threshold voltages Vth of the transistors constituting the circuit by appropriate mask design.

As described above, by setting the channel length L and the channel widths W′ and W appropriately, the current value of the current IG of the switchable current source 52 is invariable in the range of variations of the threshold voltage Vth of the NMOS transistor 15.

The slew rate of the external output signal SC is determined mainly with the capacitance value Cgd of the gate-drain capacitance of the NMOS transistor 15, which is not shown in FIG. 5, and the current value of the current IG. That is, the slew rate can be approximated by Expression (1).

Slew rate≈(current value of IG/Cgd) (1)

Since the gate-drain capacitance Cgd is independent of the threshold voltage Vth, it can well be concluded that the slew rate of the external output signal SC hardly has Vth dependence when the NMOS transistor 15 is turned off.

Accordingly, in Embodiment 1, variations in the slew rate of the external output signal SC with variations in the threshold voltage Vth of the NMOS transistor 15 can be reduced, not only when the NMOS transistor 15 is turned on, but also when it is turned off.

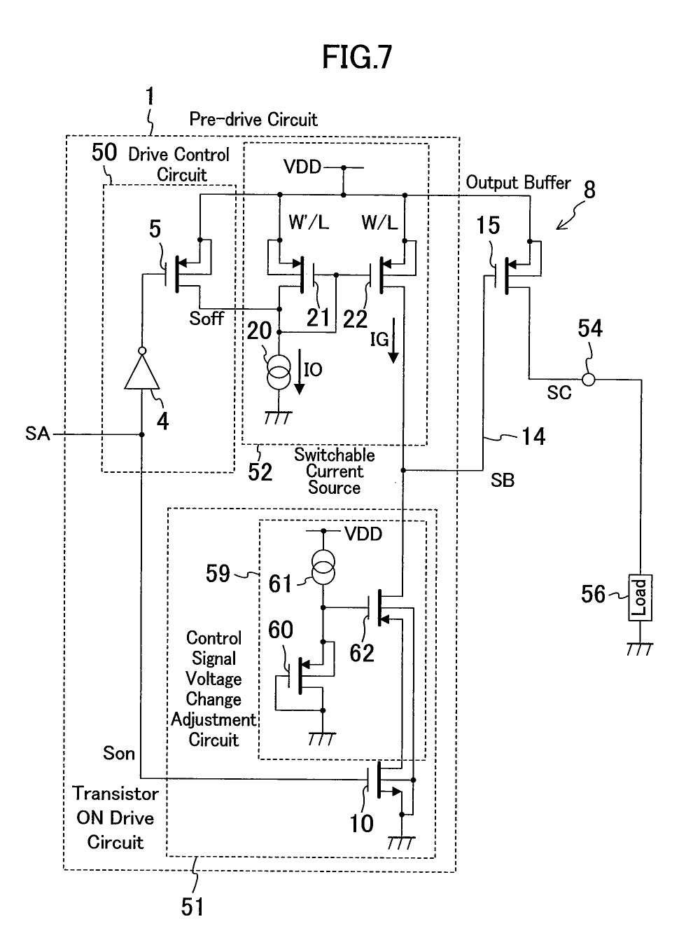

The output circuit of Embodiment 1 shown in FIG. 5 may be changed to a configuration shown in FIG. 7, in which an NMOS transistor 10 and a PMOS transistor 15 are interchanged in their roles and the load connected to the external output terminal 54 at one terminal is connected to the ground GND at the other terminal. In this case, also, variations in the slew rate of the external output signal SC with variations in the threshold voltage Vth of the PMOS transistor 15 can be reduced, not only when the PMOS transistor 15 is turned on, but also when it is turned off.

### Embodiment 2

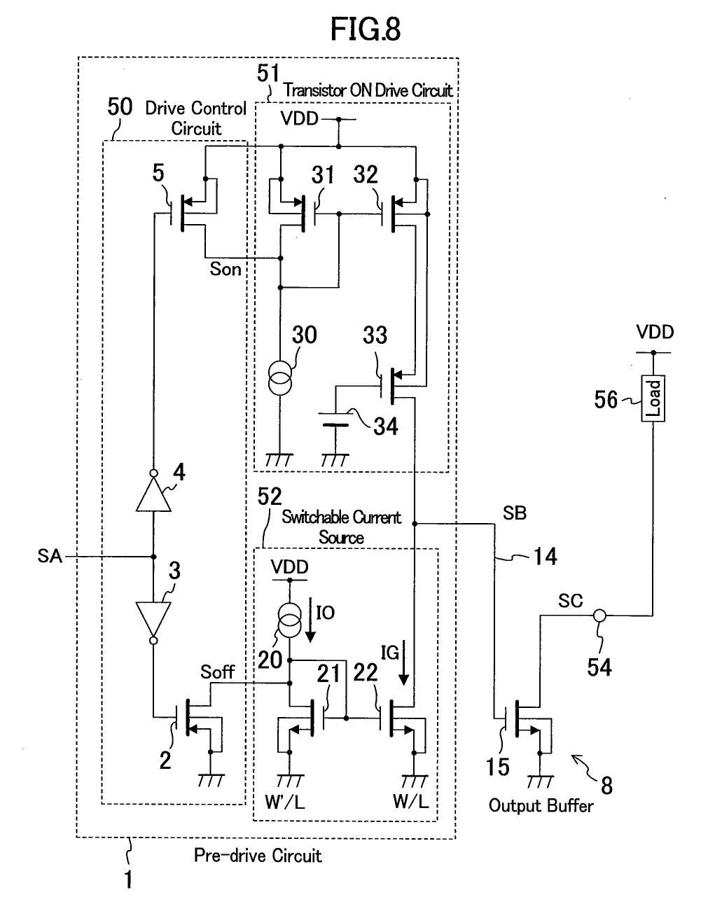

Embodiment 2 will be described with reference to FIG. 8. FIG. 8 shows an output circuit as another specific embodiment of the output circuit shown in FIG. 1. The configuration of the output circuit of Embodiment 2 shown in FIG. 8 will be described in association with FIG. 1.

The drive control circuit 50 in FIG. 1 includes two inverters 3 and 4, an NMOS transistor 2, and a PMOS transistor 5 in this embodiment. The input signal SA is input into the gate terminal of the NMOS transistor 2 via the inverter 3, and the NMOS transistor 2 outputs the signal Soff for controlling the switchable current source 52 from its drain terminal. The input signal SA is also input into the gate terminal of the PMOS transistor 5 via the inverter 4, and the PMOS transistor 5 outputs the signal Son for controlling the transistor ON drive circuit 51 from its drain terminal.

In FIG. 8, the transistor ON drive circuit 51 includes: a current mirror circuit having a PMOS transistor 31 and a PMOS transistor 32; a current source 30 connected to an input node of the current mirror circuit (the gate and drain terminals of the PMOS transistor 31 and the gate terminal of the PMOS transistor 32); a gate-grounded PMOS transistor 33 connected in series between the drain terminal of the PMOS transistor 32 and an output terminal 14 of the pre-drive circuit 1; and a voltage source 34 connected to the gate terminal of the PMOS transistor 33.

The signal Son from the drive control circuit 50 is connected to the drain and gate terminals of the PMOS transistor 31 of the transistor ON drive circuit 51. When the input signal SA is high, this node goes high, turning off the transistor ON drive circuit 51 and thus dropping the current values of the drain currents of the PMOS transistors 32 and 33 as the output current of this circuit to zero.

The output current of the transistor ON drive circuit 51, which is based on the drain current of the PMOS transistor 32, has an approximately fixed current value irrespective of fluctuations in the voltage at the output terminal 14 of the pre-drive circuit 1 under the action of the gate-grounded PMOS transistor 33.

Therefore, as described earlier on the slew rate of the external output signal, the transistor ON drive circuit 51 can work to reduce variations in the slew rate of the external output signal SC with variations in the threshold voltage Vth of the NMOS transistor 15, if any, when the NMOS transistor 15 is turned on.

The switchable current source 52, the output buffer 8, and the load 56 in FIG. 8 are the same in configuration as those of the output circuit of Embodiment 1 shown in FIG. 5, and the operations and effects thereof are also the same.

Accordingly, in Embodiment 2, variations in the slew rate of the external output signal SC with variations in the threshold voltage Vth of the NMOS transistor 15 can be reduced, not only when the NMOS transistor 15 is turned on, but also when it is turned off.

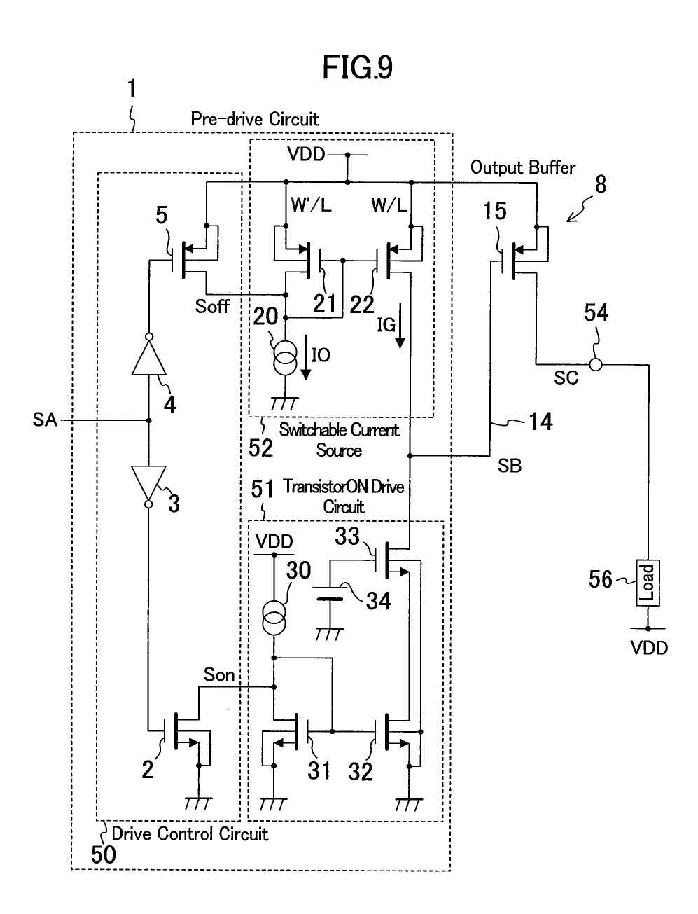

The output circuit of Embodiment 2 shown in FIG. 8 may be changed to a configuration shown in FIG. 9, in which a PMOS transistor 15 is changed in its role and the load 56 connected to the external output terminal 54 at one terminal is connected to the ground GND at the other terminal. In this case, also, variations in the slew rate of the external output signal SC with variations in the threshold voltage Vth of the NMOS transistor 15 can be reduced, not only when the PMOS transistor 15 is turned on, but also when it is turned off.

### Embodiment 3

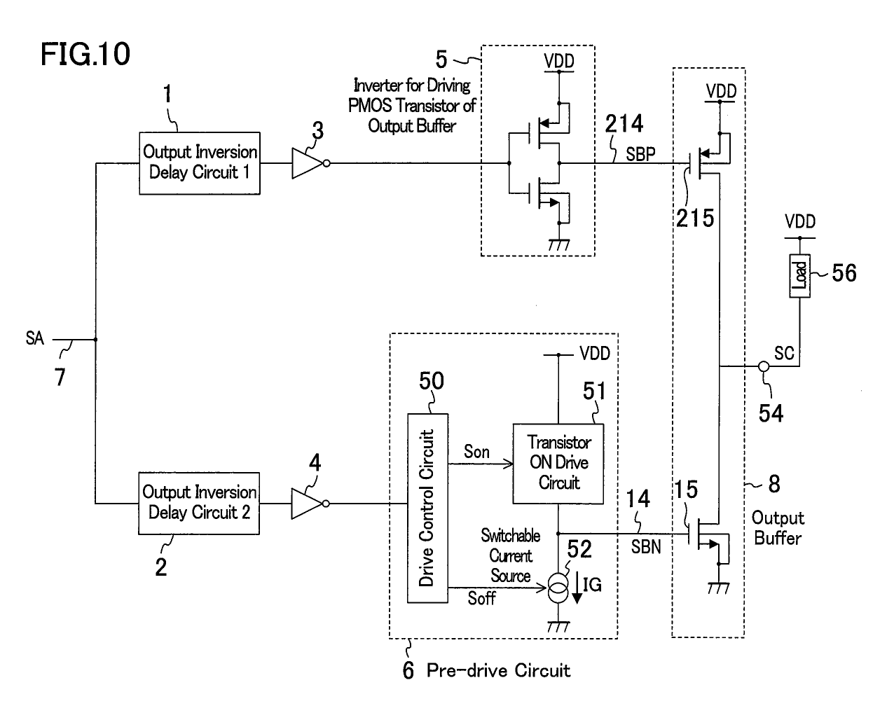

Embodiment 3 will be described with reference to FIG. 10. In an output circuit of FIG. 10, the output buffer 8 includes the NMOS transistor 15 and a PMOS transistor 215. This output circuit can both pull in and push out the output current at the external output terminal 54.

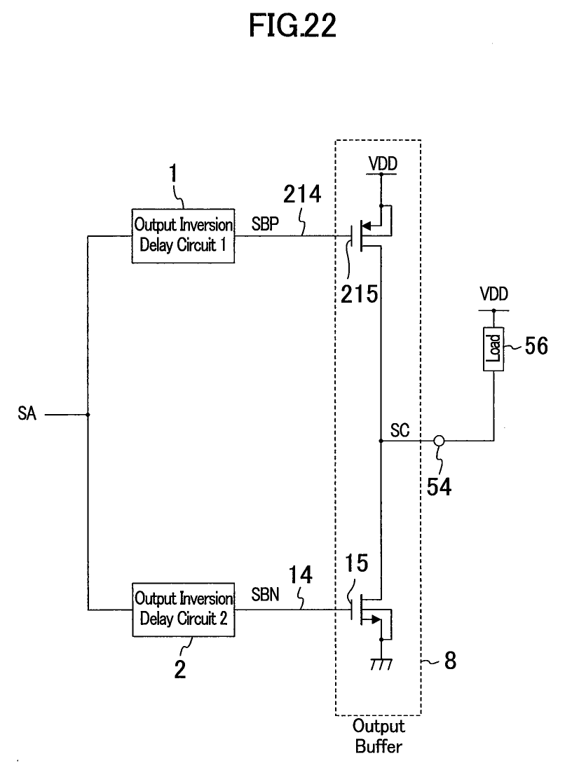

The output circuit of this embodiment is basically the same in configuration as the output circuit described above with reference to FIG. 22 configured to prevent occurrence of a shoot through current condition of the NMOS transistor 15 and the PMOS transistor 215 of the output buffer 8, and thus has the effect of preventing occurrence of a shoot through current condition.

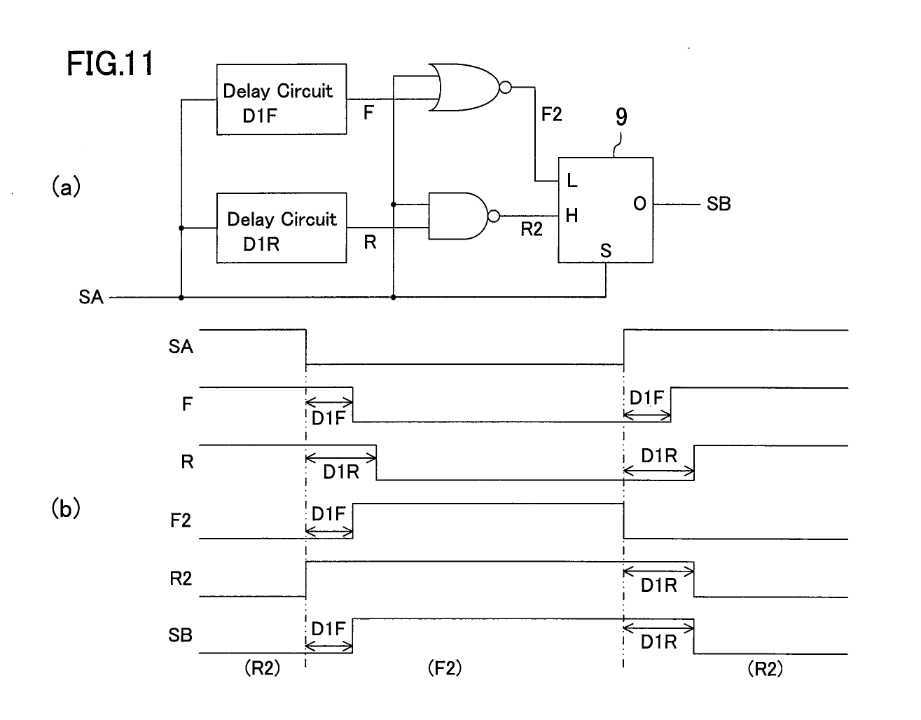

An output inverted delay circuit 1 shown in FIG. 10 has a logic circuit configuration shown in FIG. 11A.

In FIG. 11A, two delay circuits D1F and D1R have respective delay times D1F and D1R different from each other. A selector 9 selects a signal R2 when the input signal SA is high or a signal F2 when it is low, and outputs the selected signal as a signal SB.

In the above logic circuit, as shown in the timing chart of FIG. 11B, when the input signal SA makes a high to low transition, the output signal SB is output as an inverted signal SA after the delay time D1F. When the input signal SA makes a low to high transition, the output signal SB is output as an inverted signal SA after the delay time DIR.

An output inverted delay circuit 2 shown in FIG. 10 is the same in configuration and operation as the output inverted delay circuit 1 described with reference to FIGS. 11A and 11B, except that the delay time at the high to low transition is D2F and the delay time at the low to high transition is D2R. Although the four delay times D1F, D1R, D2F, and D2R are different from one another in the illustrated example, they may be the same depending on the circuit design.

In the circuit configuration shown in FIG. 10, a pre-drive circuit 6 configured to output the signal SBN for driving the gate of the NMOS transistor 15 of the output buffer 8 is the same as the pre-drive circuit 1 in Embodiment 1 shown in FIG. 5 or the pre-drive circuit 1 in Embodiment 2 shown in FIG. 8.

An inverter circuit 5 shown in FIG. 10 is an inverter for driving the PMOS transistor 215 of the output buffer 8.

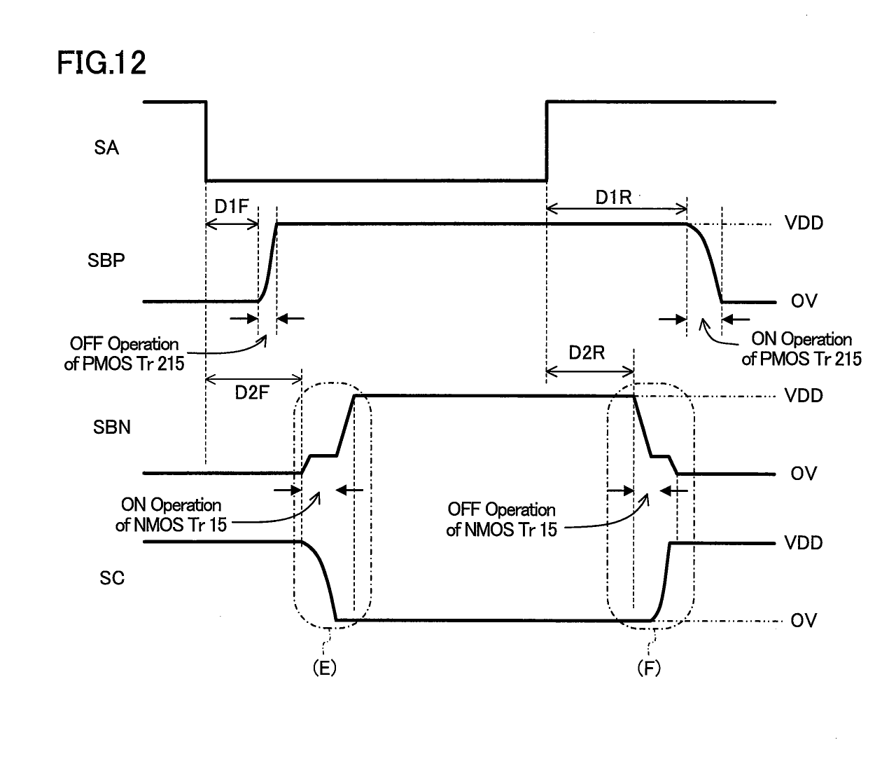

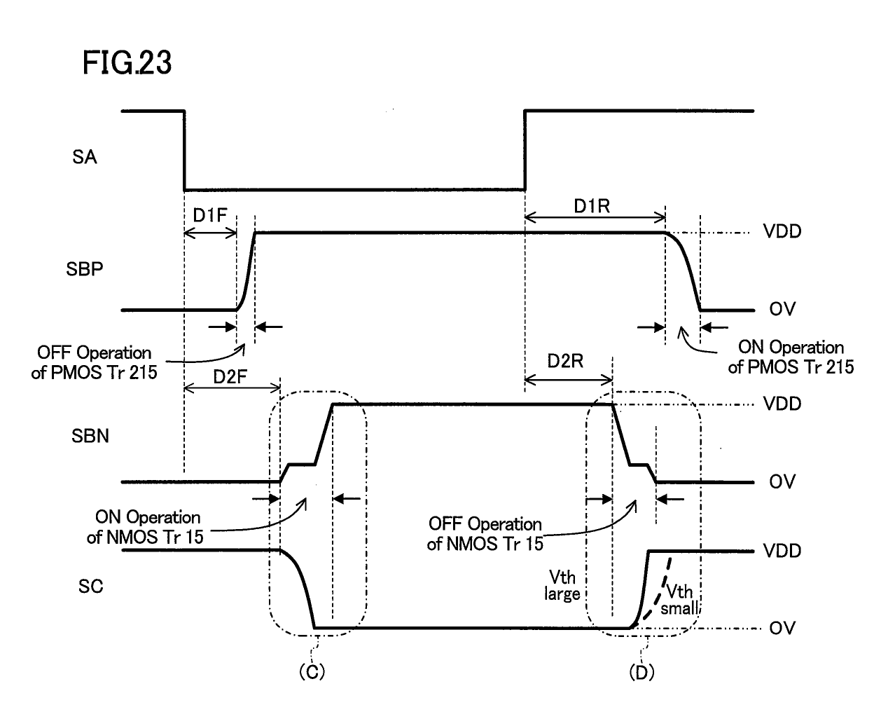

The operation of the output circuit of FIG. 10 is as illustrated in a signal waveform chart of FIG. 12, which is the same timing chart as that of FIG. 23 used for describing the operation of the output circuit of FIG. 22. The output circuit of FIG. 10 can prevent occurrence of a shoot through current condition of the NMOS transistor 15 and the PMOS transistor 215 with the delay times D2F and D1R as already described.

The slew rates of the external output signal SC at its high to low transition and low to high transition are determined with the ON and OFF operations of the NMOS transistor 15. Since the pre-drive circuit 6 configured to output the signal SBN for driving the gate of the NMOS transistor 15 is the same as the pre-drive circuit 1 in Embodiment 1 shown in FIG. 5 or the pre-drive circuit 1 in Embodiment 2 shown in FIG. 8, variations in the slew rate of the external output signal SC with variation in the threshold voltage Vth of the NMOS transistor 15 can be reduced.

Accordingly, the output circuit of Embodiment 3 can both pull in and push out the output current at the external output terminal while preventing occurrence of a shoot through current condition of the NMOS transistor 15 and the PMOS transistor 215 of the output buffer 8, and also has the effect of reducing variations in the slew rate of the external output signal SC even when the NMOS transistor 15 of the output buffer 8, which determines the slew rate of the external output signal SC, varies in its threshold voltage Vth.

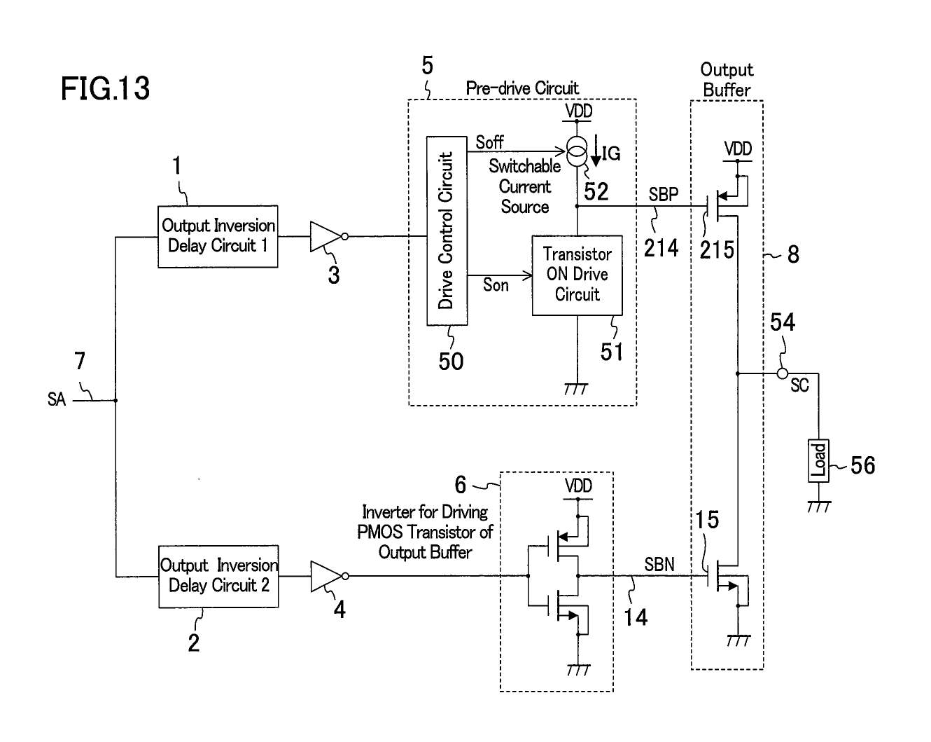

In Embodiment 3 shown in FIG. 10, the load 56 connected to the external output terminal 54 at one terminal is connected to the power supply VDD at the other terminal. Alternatively, an output circuit configuration shown in FIG. 13 may be adopted, in which the other terminal of the load 56 is connected to the ground GND.

The configuration of the output circuit of FIG. 13 is different from that of FIG. 10 in that the gate terminal of the NMOS transistor 15 of the output buffer 8 is connected to an inverter 6 for driving the NMOS transistor 15 and the gate terminal of the PMOS transistor 215 of the output buffer 8 is connected to a pre-drive circuit 5. The pre-drive circuit 5 is the same as the pre-drive circuit 1 in Embodiment 1 shown in FIG. 7 or the pre-drive circuit 1 in Embodiment 2 shown in FIG. 9.

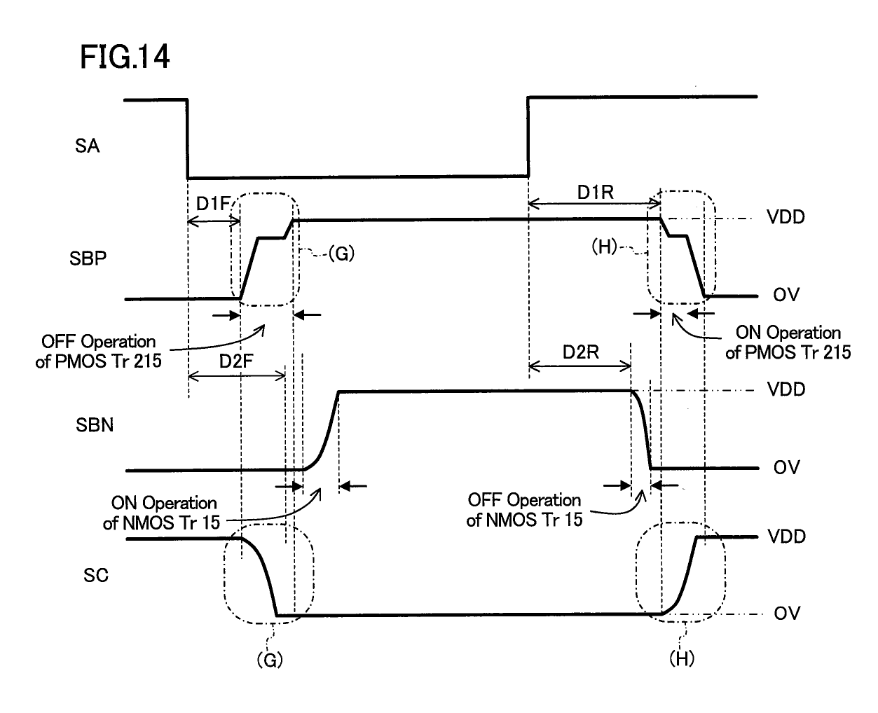

The operation of the output circuit of FIG. 13 is as illustrated in a signal waveform chart of FIG. 14. Occurrence of a shoot through current condition of the NMOS transistor 15 and the PMOS transistor 215 can be prevented with the delay times D2F and DIR.

The slew rates of the external output signal SC at its high to low transition and low to high transition are determined with the ON and OFF operations of the PMOS transistor 215. Since the pre-drive circuit 5 configured to output the signal SBP for driving the gate of the PMOS transistor 215 is the same as the pre-drive circuit 1 in Embodiment 1 shown in FIG. 7 or the pre-drive circuit 1 in Embodiment 2 shown in FIG. 9, variations in the slew rate of the external output signal SC with variation in the threshold voltage Vth of the PMOS transistor 215 can be reduced.

### Embodiment 4

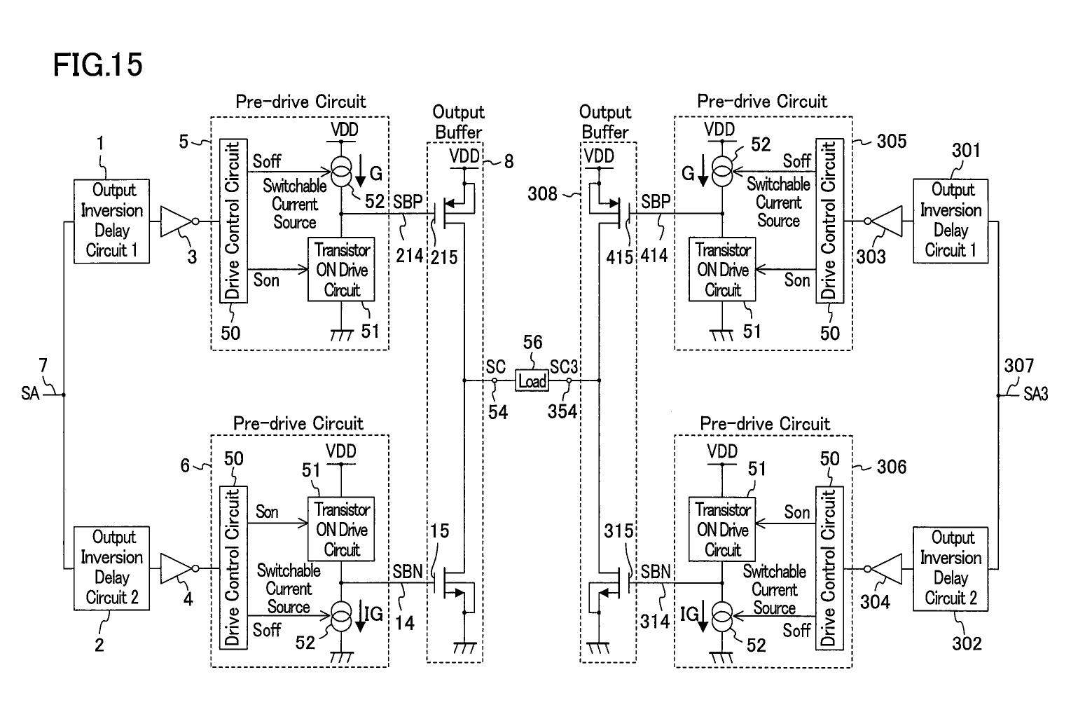

Embodiment 4 will be described with reference to FIG. 15. An output circuit of FIG. 15 has two input terminals 7 and 307 and two external output terminals 54 and 354. This output circuit is constructed of two output circuits having the same configuration, in which the output circuit on the left as viewed from FIG. 15 having the input terminal 7 and the output terminal 54 is the same in circuit configuration and operation as the output circuit on the right having the input terminal 307 and the output terminal 354. Therefore, the circuit configuration of only the left-side output circuit will be described.

The left-side output circuit in FIG. 15 is the same in configuration as the output circuit of Embodiment 3 shown in FIG. 10, except that the pre-drive circuit 1 in Embodiment 1 or 2 shown in FIG. 7 or 9, in place of the inverter for driving the PMOS transistor 215, is connected, at its output terminal, to the gate terminal of the PMOS transistor 215 of the output buffer 8. The load 56 is connected between the two external output terminals 54 and 354.

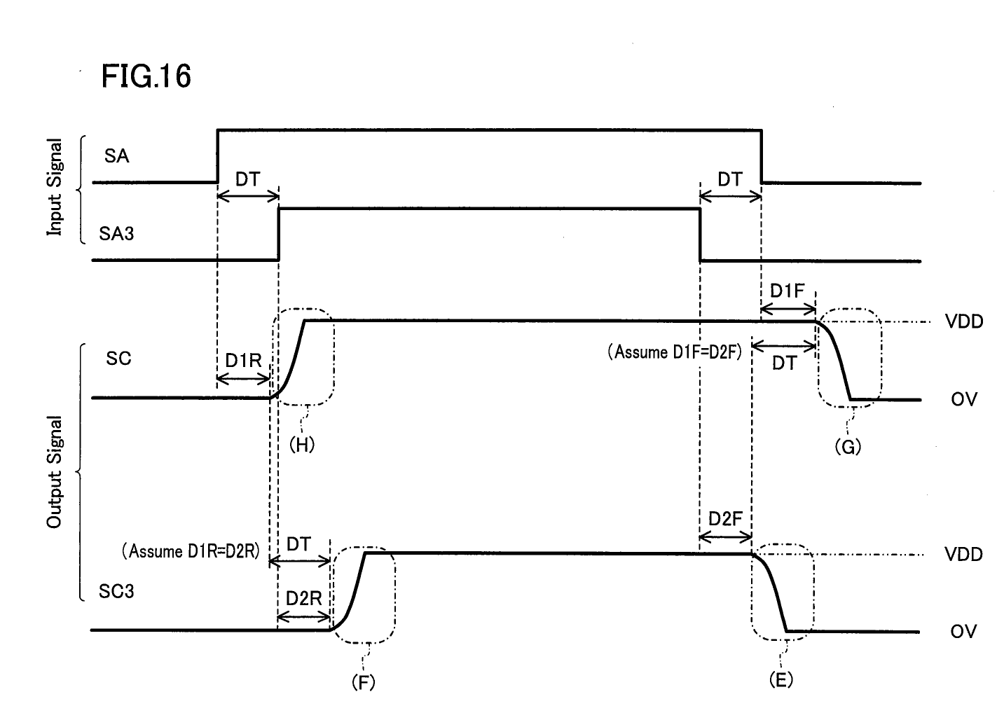

The operation of the output circuit of this embodiment will be described with reference to FIG. 16. The output circuit outputs the output signal SC at the output terminal 54 and an output signal SC3 at the output terminal 354 giving a time difference between pulses of the output signals SC and SC3 by a time difference between pulses of the input signal SA at the input terminal 7 and an input signal SA3 at the input terminal 307. Therefore, in this output circuit, an amount of power proportional to the time difference DT between the two input signals can be applied to the load 56 connected between the two output terminals 54 and 354. The operation of this output circuit will be described as follows.

First, after the lapse of the delay time D1R from a low to high transition of the input signal SA, the output signal SC makes a low to high transition as in the state shown by (H) in FIG. 16. In the state (H), since the output signal SC3 at the output terminal 354 is low, the output signal SC makes the low to high transition with the ON operation of the PMOS transistor 215 of the left-side output circuit in FIG. 15.

Secondly, after the lapse of the time DT from the low to high transition of the input signal SA, the input signal SA3 makes a low to high transition. Thereafter, after the lapse of the delay time D2R, the output signal SC3 makes a low to high transition as in the state shown by (F) in FIG. 16. In the state (F), since the output signal SC at the output terminal 54 is high, the output signal SC3 makes the low to high transition with the OFF operation of the NMOS transistor 315 of the right-side output circuit in FIG. 15.

When the two delay times D1R and D2R are set equal to each other, the time difference between the transition (H) of the output signal SC and the transition (F) of the output signal SC3 is DT.

Thirdly, after the lapse of the delay time D2F from a high to low transition of the input signal SA3, the output signal SC3 makes a high to low transition as in the state shown by (E) in FIG. 16. In the state (E), since the output signal SC at the output terminal 54 is high, the output signal SC3 makes the high to low transition with the ON operation of the NMOS transistor 315 of the right-side output circuit in FIG. 15.

Fourthly, after the lapse of the time DF from the high to low transition of the input signal SA3, the input signal SA makes a high to low transition. Thereafter, after the lapse of the delay time D1F, the output signal SC makes a high to low transition as in the state shown by (G) in FIG. 16. In the state (G), since the output signal SC3 at the output terminal 354 is low, the output signal SC makes the high to low transition with the OFF operation of the PMOS transistor 215 of the left-side output circuit in FIG. 15.

When the two delay times D1F and D2F are set equal to each other, the time difference between the transition (G) of the output signal SC and the transition (E) of the output signal SC3 is DT.

As is found from the above description of the operation, when the two input signals SA and SA3 are given as shown in FIG. 16, the transitions of the output signals SC and SC3 at the two output terminals of this output circuit are determined with the ON and OFF operations of the PMOS transistor 215 and the NMOS transistor 315. The PMOS transistor 215 is driven with the pre-drive circuit 5 in FIG. 15, while the NMOS transistor 315 is driven with the pre-drive circuit 306 in FIG. 15. These pre-drive circuits 5 and 306 are respectively the same as the pre-drive circuit 1 in FIG. 7 or 9 and the pre-drive circuit 1 in FIG. 5 or 8 in Embodiment 1 or Embodiment 2. Accordingly, in this output circuit, variations in the slew rates of the output signals SC and SC3 in their transition states (H), (F), (E), and (G) shown in FIG. 16 with variations in the threshold voltages Vth of the NMOS transistor 315 and the PMOS transistor 215 are reduced.

Accordingly, in the output circuit of Embodiment 4, by giving a time difference between pulses of the two output signals SC and SC3 at the two output terminals 54 and 354 by the time difference DT between pulses of the two input signals SA and SA3, an amount of power proportional to the time difference DT between the two input signals is applied to the load 56 connected between the output terminals 54 and 354. Even when the threshold voltages Vth of the NMOS transistors 15 and 315 and the PMOS transistors 215 and 415 of the output circuit vary, variations in slew rate at state transitions of the output signals can be reduced. As a result, variations in the power proportional to the time difference DT applied to the load 56 can be reduced.

### Embodiment 5

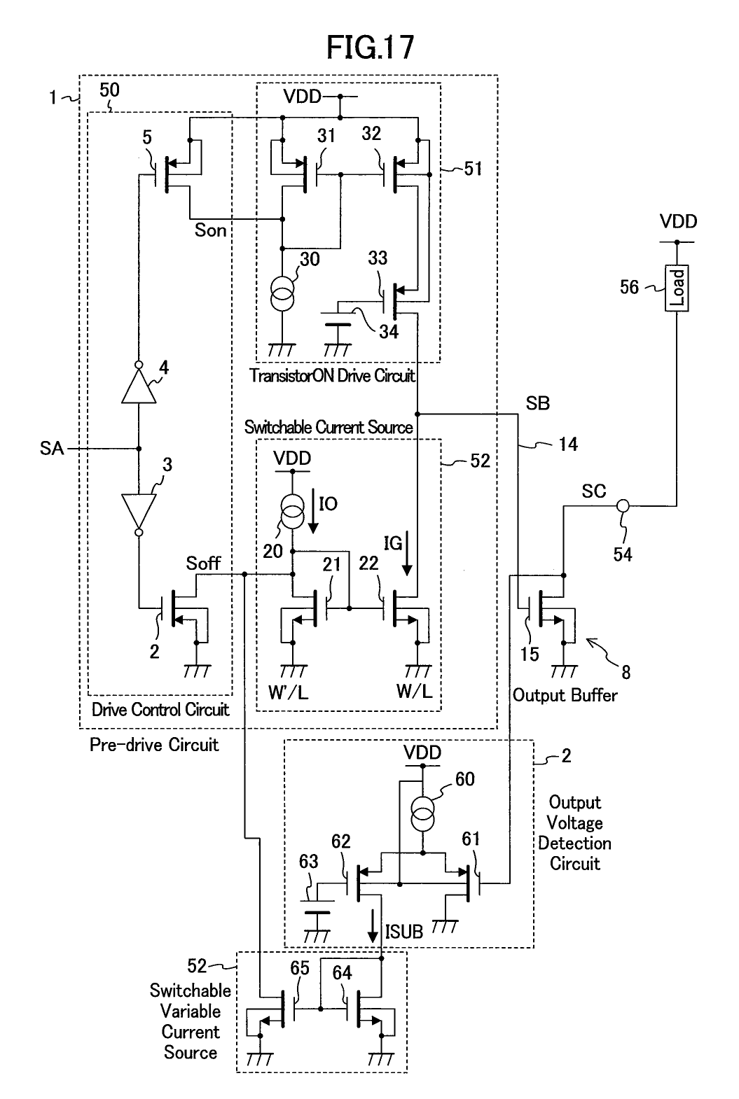

Embodiment 5 will be described with reference to FIG. 17.

The output circuit of FIG. 17 is a circuit having the following components added to the output circuit of Embodiment 2 shown in FIG. 8: a differential circuit constructed of a PMOS transistors 61 and 62; a current source 60 determining a tale current of the differential circuit; a voltage source 63 connected to the gate of the PMOS transistor 62 serving as one input terminal of the differential circuit; an NMOS transistor 64 whose gate and drain terminals are connected to the drain terminal of the PMOS transistor 62; and an NMOS transistor 65 whose gate terminal is connected to the drain terminal of the PMOS transistor 62.

The NMOS transistors 64 and 65 constitute a current mirror circuit. This current mirror circuit, which is part of the switchable variable current source 52, serves to add a mirror current of an output current ISUB from the differential circuit constructed of the two PMOS transistors 61 and 62 to the original current of the current source 20 for the current mirror circuit constructed of the two NMOS transistors 21 and 22, which is also part of the switchable variable current source 52.

The differential circuit constructed of the two PMOS transistors 61 and 62, the current source 60 determining the tale current of the differential circuit, and the voltage source 63 connected to the gate of the PMOS transistor 62 constitute the output voltage detection circuit 2. The gate terminal of the PMOS transistor 61 serving as the other input terminal of the differential circuit is connected to the drain terminal of the NMOS transistor 15 of the output buffer 8. The differential circuit detects the voltage value of the external output signal SC, compares the detected value to the voltage value of the voltage source 63, and, if the voltage value of the external output signal SC is higher than the voltage value of the voltage source 63, outputs the output current ISUB to the switchable variable current source 52 as the current value change signal.

The switchable variable current source 52 outputs the current IG determined with the current of the current source 20 if the current ISUB as the current value change signal is zero, or outputs the current IG determined with a current obtained by subtracting the current ISUB from the current of the current source 20 if the current ISUB has a value.

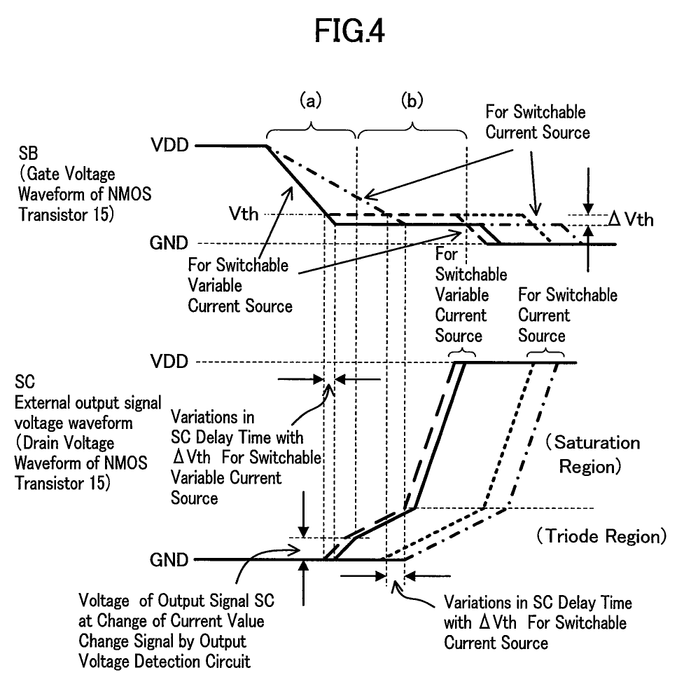

Having the circuit configuration described above, the current value of the current IG of the switchable variable current source 52 can be kept at a large value during the time period in which the voltage of the external output signal SC (drain terminal voltage) reaches the voltage value of the voltage source 63 from a low level (approximately 0 V). This time period refers to the period (a) in FIG. 4.

As already described with reference to FIG. 4, in the output circuit having the above configuration, by setting the current value of the current IG appropriately during the period (b), after the period (a), in which the output voltage reaches a high level (power supply voltage VDD) from the voltage value of the voltage source 63, it is possible to set a desired output voltage slew rate.

Accordingly, in the output circuit having the above configuration, by setting different current values for the current IG between the periods (a) and (b) in FIG. 4, the out voltage slew rate can be set to a desired value when the NMOS transistor 15 is turned off, as in the output circuit using the switchable current source described above. Also, since the current value of the current IG is invariable even when the threshold voltage Vth varies, it is possible to obtain the effect of reducing variations in the slew rate of the external output signal when the NMOS transistor 15 is turned off. In addition, unlike the output circuit using the switchable current source described above, an effect of reducing variations in the delay time from the input signal SA to the output signal SC can be obtained even when the threshold voltage Vth varies.

What is claimed is:

1. An output circuit, comprising:
a pre-drive circuit configured to receive an input signal and output a drive signal; and
a source-grounded, open-drain transistor configured to receive the drive signal from the pre-drive circuit at its gate terminal and outputs an external output signal from its drain terminal,
wherein
the pre-drive circuit comprises:
a transistor ON drive circuit configured to output the drive signal for turning on the source-grounded, open-drain transistor;
a switchable current source configured to output the drive signal for turning off the source-grounded, open-drain transistor; and
a drive control circuit configured to output control signals for controlling the transistor ON drive circuit and the switchable current source in response to receipt of the input signal, and
the switchable current source is connected to the gate terminal of the source-grounded, open-drain transistor at its one terminal and to the ground at the other terminal, and electric charge at the gate terminal of the source-grounded, open-drain transistor is pulled out with the current of the switchable current source at a fixed current value even when the gate voltage of the source-grounded, open-drain transistor varies in a range of variations of the threshold voltage of the transistor.

2. The output circuit of claim 1, wherein
the switchable current source is comprised of a switchable variable current source capable of changing the current value of the current of the switchable current source with a current value change signal, and
the circuit further comprises:
an output voltage detection circuit configured to change the value of the current value change signal once the external output signal of the output circuit reaches a given voltage value and output the changed current value change signal to change the current value of the switchable variable current source.

3. The output circuit of claim 1, wherein
the source-grounded, open-drain transistor is constructed of an NMOS transistor.

4. The output circuit of claim 1, wherein
the source-grounded, open-drain transistor is constructed of a PMOS transistor.
